(19) United States
(12) Patent Application Publication
(10) Pub. No.: US 2006/0278982 A1
(43) Pub. Date: Dec. 14, 2006

(54) Metal bump with an insulation for the side walls and method of fabricating a chip with such a metal bump

(75) Inventor: Jose Solo De Zaldivar, Waedenswil (CH)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., Eindhoven (NL)

(21) Appl. No.: 10/564,236

(22) PCT Filed: Jul. 8, 2004
(86) PCT No.: PCT/IB04/51175

§ 371 Date: Jan. 10, 2006

(30) Foreign Application Priority Data
Jul. 16, 2003 (EP) 03102190.0

(51) Int. Cl. H01L 23/48; H01L 21/44

(52) U.S. Cl. 257/737; 438/613; 438/614; 257/781

(57) ABSTRACT

A chip with at least two metal bumps (6a, 6b) which has insulation layers for opposing side walls which are deposited in a plasma activated gas. Predetermined portions of the insulation layer (7) are removed by reactive ion etching. The metal bumps can be formed of a noble metal and the insulation layer of a dielectric material such as SiO₂Si₃N₄.

The invention relates to a metal bump on an IC with an insulation for the side walls. The invention relates especially to a driver IC for a Liquid Crystal Display (LCD) module that is attached to a glass panel. The invention also relates to a method of fabricating a chip comprising such a bump. The invention further relates to a connector for a chip's substrate and a glass panel or a foil.

Anisotropic Contact Films (ACF) is a common material for attaching the chip to the glass panel. It is an adhesive film consisting of dispersed, microscopic, electrically conductive particles 3-15 μm in diameter and an adhesive 15-35 μm thickness. A limitation of the ACF assembly technique is due to the fact that the probability of shorts between adjacent bumps increases rapidly by decreasing the gap between them. The formation of chains of conductive balls touching the side walls of two adjacent bumps may short them together. The ACF assembly technique is specially used for Chip On Glass (COG) and Chip on Foil (COF) advanced packaging applications.

US patent application US 2002/0048924 A1 discloses metal bumps that comprise at least a first metal bump having a first side wall, the first side wall comprising a first predetermined area; and at least a second metal bump having a second side wall, the second side wall comprising a second predetermined area adjacent to the first predetermined area; wherein at least the first predetermined area is covered with an insulated layer. The insulating layer may cover the entire side wall of both the first and the second metal bump. Predetermined portions of the first metal bump may be covered with an insulating layer. This results in preventing electrical shorts caused by the conductive particles. In US 2002/0048924 A1 it is disclosed to use a silicon-oxide (SiO2) or silicon-nitride (Si3N4) as material for the insulating layer on the side walls.

U.S. Pat. No. 6,232,563 B1 concerns a connector structure for connecting a semiconductor device to an external terminal using an adhesive material including a plurality of conductive elements. The connector structure includes a pad over the device's substrate, an electrically conductive bump over the pad connected to the external terminal's pad using a conductive adhesive material comprising a plurality of conductive elements and an insulating layer on a side surface of the electrically conductive bump, the insulating layer substantially covering an entire side surface of the electrically conductive bump to prevent an electrical short through the side surface. The disclosed method of fabricating such a connector structure comprises the steps of
i. forming a pad of a conductive material such as aluminium on a substrate on which a driving device is formed,
ii. forming a passivation layer such as a silicon oxide layer or silicon nitride layer on the overall surface of the substrate including the pad,
iii. selectively etching the passivation layer to expose a portion of the pad such that a portion of the passivation layer covers the edge of the pad,
iv. depositing a barrier layer (for example, TiW/Au, Ti/PtAu) on the exposed portion of the pad and a passivation layer,
v. selectively forming a photo resist pattern on the barrier metal to expose a portion of the barrier metal on the pad,
vi. forming a bump of gold (Au) on the barrier metal by electroplating using the photo resist pattern,
vii. removing the photo resist pattern,
viii. selectively etching the barrier metal to form a diffusion stop portion,
ix. carrying out a heat treatment,
x. forming an insulating layer, such as a polymer, photosensitive polymer, or silicon nitride layer on the bump, the passivation layer and the exposed portion of the diffusion stop portion through chemical vapor deposition (CVD), physical vapor deposition (PVD) or coating, for example,
xi. coating a photo resist on the insulating layer and
xii. selectively removing the photo resist to form a photo resist pattern defining a contact region on the bump,
xiii. etching the insulating layer using the photo resist pattern as a mask or by photo process (in the case of a photosensitive material),
xiv. removing the photo resist pattern to complete the bump electrode.

The method proposed in U.S. Pat. No. 6,232,563 B1 requests a mask step where a photo resist is coated on the insulating layer and selectively removed to form a photo resist pattern defining a contact region on the bump where the insulating layer is portionally etched. Then the photo resist pattern is removed.

It is an object of the invention to further develop the method of fabricating a bump according to the generic introduction. It is another object of the invention to provide a connector that is fabricated in an improved manner. It is a further object of the invention to provide metal bumps that can be easily fabricated.

As regards the method the object is solved by a method as described in claim 1. The deposited metal layer covering the chip's passivation layer and the metal pads serves as an etch stop during the etching of the insulating layer plasma. The insulation layer is deposited in a low pressure plasma activated gas where the molecules are split up into ions and electrons facilitating the reaction and increasing the deposition rate. Subsequently the use an special method based on RIE (Reactive Ion Etching) for removing the predetermined (horizontal regions on the IC surface) portions of the insulation layer simplifies the method for fabricating the chip and does help to reduce costs and processing time as those mask steps comprising the steps of (xi.) coating a photo resist on the insulation layer, (xii.) selectively removing the photo resist to form a photo resist pattern defining a contact region on the bump and (xiv.) removing the photo resist pattern to complete the bump electrode are dropped.

As regards the connector, the object is solved by a connector as described in independent claim 2. The low pressure chemical vapor deposition (LPCVD) is a process whose reaction velocity is kinetically controlled, which means that the reaction velocity is temperature-dependent. This process enables the formation of layers that have a uniform layer thickness on horizontal regions and vertical walls of the IC surface topography. The insulation layer may be formed of silicon dioxide (SiO₂) which is formed by a reaction of silane (SiH₄) or dichlorosilane (SiH₂Cl₂) with an oxidising agent such as NO or N₂O₄. The reaction takes place in the temperature range between 430° and 633° C. at a pressure of approximately 1 mbar. The activation energy of the reaction with N₂O₄ is 0.91 eV/molecule, which corresponds to 87.4 kJ/mol. This temperature range makes the method suitable for the application of a SiO₂-layer on glass, aluminium and many metal-silicides.

As regards the metal bumps the object is solved in that the insulation layer of at least two opposite side walls of two metal bumps is provided by an LPCVD process at subatmospheric pressures. Reduced pressures tend to reduce unwanted gas phase reactions and improve film uniformity across the wafer.

According to one embodiment the insulation layer is a dielectric layer which is formed by plasma deposition and is partially etched back in an anisotropic plasma etcher. The anisotropic plasma etcher can immediately be used without performing a mask step.

According to one embodiment, the dielectric material forming the insulation layer is part of the group including SiO₂ or Si₃N₄. These dielectric materials are proven for the LPCVD-process.

According to another embodiment the metal bumps are formed of a noble metal or an oxidation resistance material such as gold (Au) or a metal of the platinum group. The use of a noble metal for the bump results in a surface for the contact with the electrical conductive elements (or particles) in the ACF polymer that has a low electrical resistance.

The inventive bump may especially be used for a Chip on Glass or a Chip on Foil packaging application.

An exemplary embodiment of the invention will now be described in detail with reference to the accompanying drawings where

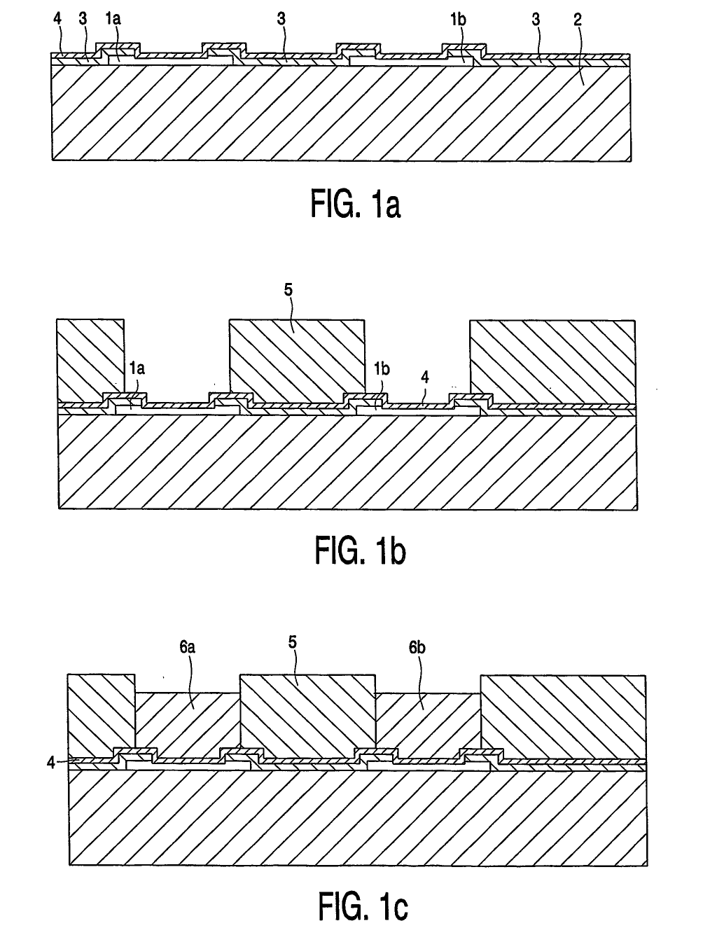

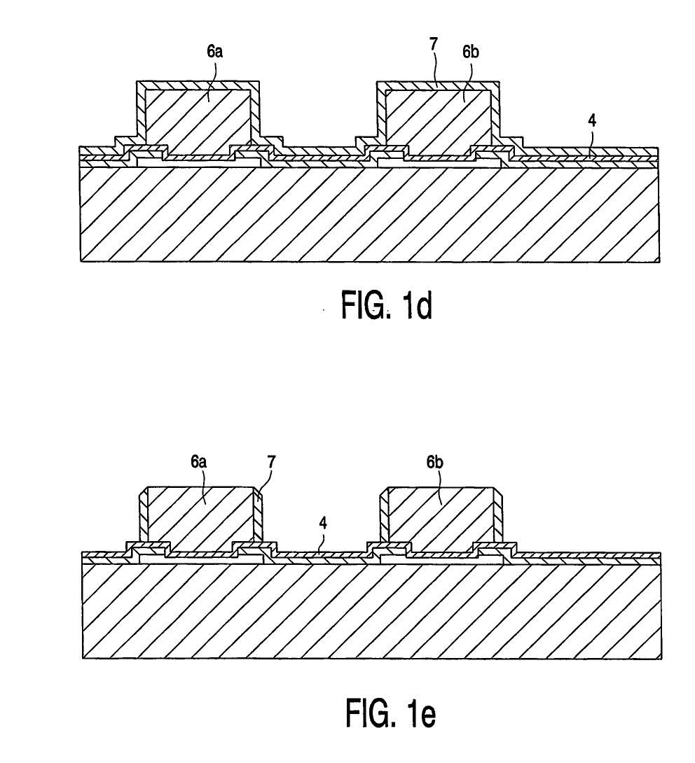

FIG. 1 shows processing steps in a cross sectional view and

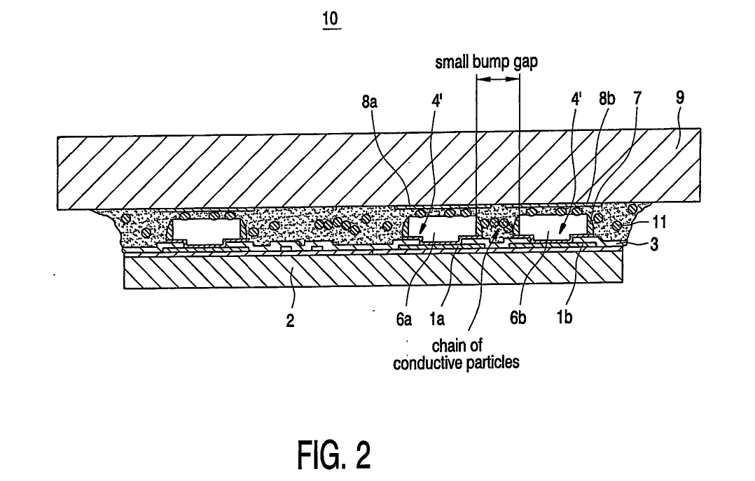

FIG. 2 shows a cross sectional view of a connector.

FIG. 1 shows processing steps in a cross sectional view. FIG. 1a) shows metal pads 1a, 1b which are added to the chip's substrate 2. A passivation layer 3 is disposed on those portions of the chip's substrate 2 which are not covered by any of the metal pads 1a, 1b and covers the edges of those metal pads 1a, 1b. An under bump metal layer 4 covers the passivation layer 3 and those portions of the metal pads 1a, 1b which are not covered by the passivation layer 3.

FIG. 1b) shows the next step with a photo resist coated on the barrier metal 4 and selectively removed to form a photo resist pattern 5 such as to expose a portion of the metal barrier 4 over the pads 1a, 1b.

FIG. 1c) shows bumps 6a, 6b formed on the exposed portions of the barrier metal 4 that are deposited using the photo resist pattern 5.

In FIG. 1d) the photo resist pattern is removed and an insulation layer 7 is deposited on the top and the side surfaces of the bump 6a, 6b as well as on the under bump metal barrier 4. The insulating layer 7 is deposited in the plasma state of aggregation where the molecules are split up into ions and electrons.

FIG. 1e) shows the status after performing a reactive plasma etching. Those portions of the metal layer 4 which are exposed between the side walls are then removed. The insulation layers covering the vertical walls of the bumps 6a, 6b remain because of the anisotropic character of the RIE process. The remaining portions of the metal layer 4 form a diffusion stop barrier 4′ as shown in FIG. 2.

FIG. 2 schematically shows a cross-sectional view of a connector 10 according to the invention. Connector 10 connects the chip's substrate 2 to an opposite substrate 9 such as a glass panel or a foil. The electric connection occurs via the metal pads 1a, 1b on the chip's substrate 2, the diffusion stop barrier 4′, the bumps 6a, 6b, conductive particles 11 and electrode pads 8a, 8b. There is a gap between two bumps 6a, 6b. If the gap is small enough a chain of conductive particles 11 may touch the side walls of both bumps 6a, 6b. Nevertheless, the electric circuit is prevented from a short as the side walls of the bumps 6a, 6b are covered with an insulation layer 7.

1. A method of fabricating a chip with an insulation layer for the side walls of metal bumps with the chip comprising
a non-conductive chip's substrate
metal pads deposited on the non-conductive chip's substrate
a passivation layer covering the non-conductive chip's substrate and the edges of the metal pads
a metal diffusion stop barrier covering a portion of the chip's passivation layer and the metal pads
a photo resist pattern on a metal layer to expose portions of the metal layer on the pad that is removed after use and
at least one bump on the exposed portion of the pad and the edges of the metal layer
characterized by the steps of
depositing the metal layer covering the chip's passivation layer and the metal pads
depositing an insulation layer in a plasma activated reactor,
removing predetermined portions of the insulation layer by reactive ion etching and
partially removing the metal layer such that the remaining metal material forms the bump diffusion stop barrier

2. A connector for a chip's substrate and an opposite substrate comprising:
a plurality of electrode pads on the opposite substrate
a plurality of electrically conductive bumps on the chip's substrate each of the electrically conductive bumps being electrically connected to a respective one of the plurality of electrode pads on the opposite substrate
a plurality of conductive particles on respective top surfaces of the electrically conductive bumps electrically connecting respective electrically conductive bumps to the plurality of electrode pads and
an insulating layer formed of a nitrate or an oxide on the surfaces of the side walls of each of the plurality of electrically conductive bumps to prevent an electrical short between two bumps
characterized in that the insulation layer is provided by an LPCVD-process.

3. Metal bumps that comprise side walls that are covered with an insulation layer on at least two opposite side walls facing each other, characterized in that the insulation layer is a dielectric layer which is formed by plasma deposition and is partially etched back in an anisotropic plasma etcher.

4. Metal bumps as claimed in claim 3, characterized in that the dielectric material is selected from the group consisting of SiO2 and Si3N4.

5. Metal bumps as claimed in claim 3 characterized in that the metal bumps are formed of a noble metal or an oxidation resistant material such as gold.

6. Use of a metal bump that is partially covered with an insulation layer which is deposited by an LPCVD process for a Chip on Glass or a Chip on Foil packaging application.

7. An arrangement with a chip's substrate and an opposite substrate comprising:
a plurality of electrode pads on the opposite substrate
a plurality of electrically conductive bumps, on the chip's substrates each of the electrically conductive bumps being electrically connected to a respective one of the plurality of electrode pads on the opposite substrate
a plurality of conductive particles on respective top surfaces of the electrically conductive bumps electrically connecting respective electrically conductive bumps to the plurality of electrode pads and
an insulating layer formed of a nitrate or an oxide on the surfaces of the side walls of each of the plurality of electrically conductive bumps to prevent an electrical short between two bumps
characterized in that the insulation layer His provided by an LPCVD-process.
